(19) United States
(12) Patent Application Publication
(10) Pub. No.: US 2020/0153427 A1
(43) Pub. Date: May 14, 2020

(54) Driving D-Mode FETS in Half-Bridge Driver Configuration

(71) Applicant: pSemi Corporation, San Diego, CA (US)

(72) Inventors: Arezu Bagheri, San Diego, CA (US); Buddhika Abesingha, Escondido, CA (US)

(21) Appl. No.: 16/186,323

(22) Filed: Nov. 9, 2018

(51) Int. Cl. H03K 17/687; H03K 17/22; H03K 17/06; H03K 7/08; H03K 19/0185; H03K 19/0944; H02M 3/158

(52) U.S. Cl. CPC H03K 17/687; H03K 17/223; H03K 17/063; H03K 2017/066; H03K 19/0185; H03K 19/09443; H02M 3/158; H03K 7/08

(57) ABSTRACT

Methods and devices to drive D-mode and E-mode power FETs are described. The disclosure teaches how to apply negative voltages across gate-source of D-mode FETs to turn such FETs off whenever needed. The presented method and devices can also be used in applications where overdriving D-mode FETs to achieve improved on resistance is desired.

### CROSS-REFERENCE TO RELATED APPLICATIONS

The present application may be related to U.S. Pat. No. 9,484,897 B2 issued Nov. 1, 2016, entitled “Level Shifter”, which is incorporated herein by reference in its entirety.

### BACKGROUND

### Technical Field

The present disclosure is related to half-bridge drivers, and more particularly to methods and apparatus used to drive both depletion mode (D-mode) and enhancement mode E-mode Field Effect Transistors (FETs) with a single circuit architecture.

### Background

Certain D-mode FETs are good candidates to be used for highly efficient half-bridge architectures due to their improved electrical characteristics such as high mobility, low on-resistance, and low gate capacitance. In this type of FETs, the channel is present when the gate-source voltage Vgs is zero. In other words, the FET is normally ON when there is no voltage difference between gate and source. This may cause, for example in a half-bridge architecture, an input-output short and in-rush current at startup. Therefore, new architectures are required to drive such FETs to negative gate-source voltages, thus preventing them from turning on when not needed. E-mode FETs, of course, are normally OFF when the gate-source voltage is zero, making them easier to control but at the expense of performance.

FIG. 1 shows an electronic circuit (100) comprising a half-bridge driver (101) designed to drive E-mode power FETs. The half-bridge driver (101) is connected to a load (102) and comprises high side and low side FETs (T2, T1), high side and low side drivers (DRV2, DRV1), a low side capacitor (C_{LS}), a high side capacitor (C_{HS}) and an input voltage Vin connected to high side FET (T2). High side capacitor (C_{HS}) is known as a bootstrap capacitor used in conjunction with a diode (D1) connected to power supply VDDA to power the gate of high side FET (T2) and driver (DRV2) as the half-bridge switch node (SW) transitions from LOW (zero volts in this case) to HIGH (Vin in this case). Low side driver (DRV1) drives low side FET (T1) with respect to ground, while high side driver (DRV2) drives high side FET (T2) with respect to its source which is connected directly to switch node (SW). In other words, the effective ground of high side driver (DRV2) is connected to switch node (SW).

With continued reference to FIG. 1, in a first phase of operation, when low side FET (T1) is turned on, switch node (SW) is at ground and as a result, diode (D1) is forward biased and high side capacitor (C_{HS}) is charged to VDDA-Vdiode, wherein Vdiode is the forward ON voltage of diode (D1). In a second phase of operation, when low side FET (T1) turns off, then high side FET (T2) is turned on and switch node (SW) is pulled up to the input voltage Vin. In this phase, diode (D1) is off and the charge retained in high side capacitor (C_{HS}) is used to power high side driver (DRV2) and its circuitry as well as the gate charge for high side FET (T2).

In other words, for the half-bridge driver (101) to function properly, it is crucial to charge high side capacitor (C_{HS}) periodically by turning low side FET (T1) on. This is generally not an issue, as in normal operative conditions, high side and low side FETs (T2, T1) are periodically turned on and off in non-overlapping phases providing the required condition for high side capacitor (C_{HS}) to be replenished as needed. Moreover, and as a result of driving high and low side FETs during non-overlapping phases, a square wave signal is generated at switch node (SW). As such, the shape of an output signal Vout will depend on the design of the load (102). As an example, load inductance (L) and load capacitance (C) may be chosen such that the load (102) functions as a low pass filter, filtering all the harmonics of the square wave to produce a direct current (DC) output. The ratio of the output DC signal to the input signal Vin will then depend on the duty cycle of the square wave.

With further reference to FIG. 1, and as mentioned previously, the electronic circuit (100) is designed to drive E-mode power FETs (e.g. high and low side FETs (T2, T1)). During normal operation where the FETs (T1, T2) turn on and off in non-overlapping fashion, the gate of high side FET (T2) toggles between zero and Vin+VDDA−V_{D1} and the gate of the low side FET (T1) toggles between VDDA and zero volts. The zero voltage on such gates is sufficient to turn E-mode FETs (T1, T2) off. However, if FETs T1 and T2 are D-mode, negative gate-source voltages have to be applied to turn each of them off during the appropriate half cycle.

### SUMMARY

In view of that described in the previous section, methods and devices taught in the present disclosure address the problem of driving D-mode FETs in half-bridge architectures, and by providing negative and non-negative voltages across gate-source of such devices to turn them off and on respectively. Furthermore, embodiment according to the present disclosure with architectures allowing to drive both D-mode and E-mode FETs will also be described.

According to a first aspect of the present disclosure, an electronic circuit is provided, comprising: a high side driver; a high side capacitor connected across the high side driver; a low side driver; a low side capacitor connected across the low side driver; and a charging circuit; wherein: the electronic circuit is connectable to an output load at an electronic circuit output; the low side driver is configured to selectively provide a first driving voltage and a third driving voltage to drive a power stage; the high side driver is configured to selectively provide a second driving voltage and a fourth driving voltage to drive the power stage ; and the charging circuit is connected to the high side capacitor and configured to provide power to the high side driver when the high side driver is in off state.

According to a second aspect of the present disclosure, an electronic circuit is provided, comprising: a high side driver; a high side capacitor connected across the high side driver; a low side driver; a low side capacitor connected across the low side driver; a high side switch serially connected to a low side switch at an electronic circuit output, and a charging circuit; wherein: the electronic circuit is connectable to an output load at the electronic circuit output; the high side driver is connected to the high side switch; the low side driver is connected to the low side switch; the low side driver is configured to selectively turn the high side switch on or off; the high side driver is configured to selectively turn the low side switch on or off; and the charging circuit is connected to the high side capacitor and configured to provide power to the high side driver when the high side driver is in off state.

According to a third aspect of the present disclosure, a method of generating a first, a second, a third and a fourth driving voltages is provided, comprising: providing a high side driver; connecting a high side capacitor across the high side driver; providing a low side driver; connecting a low side capacitor across the low side driver; applying a negative supply voltage to the low side driver; in a first state: configuring the low side driver to provide the first driving voltage being equal to or positive with respect to ground; charging the high side capacitor to generate a charged high side capacitor; configuring the high side driver to provide the second driving voltage being negative with respect to ground; in a second state: supplying power to the high side driver using the charged high side capacitor; configuring the low side driver to generate the third driving voltage being negative with respect to ground; and configuring the high side driver to generate the fourth driving voltage being equal to or positive with respect to ground.

Further aspects of the disclosure are provided in the description, drawings and claims of the present application.

### DESCRIPTION OF THE DRAWINGS

FIG. 1 shows a prior art electronic circuit, comprising a driver with half-bridge architecture driving E-mode power FETs.

FIG. 2A shows a half-bridge driver according to an embodiment of the present disclosure.

FIG. 2B shows a charging circuit according to an embodiment of the present disclosure.

FIG. 2C shows a charging circuit in accordance with another embodiment of the present disclosure.

FIG. 2D shows a charging circuit in accordance with yet another embodiment of the present disclosure.

FIG. 3A shows an electronic circuit in accordance with embodiments of the present disclosure.

FIG. 3B shows timing diagrams related to the embodiment of FIG. 3A.

FIG. 4A shows an electronic circuit, in accordance with embodiments of the present disclosure.

FIG. 4B shows timing diagrams related to the embodiment of FIG. 4A.

FIG. 5A shows an electronic circuit, in accordance with embodiments of the present disclosure.

FIG. 5B shows timing diagrams related to the embodiment of FIG. 5A.

FIGS. 6-8 show electronic circuits according to further embodiments of the present disclosure.

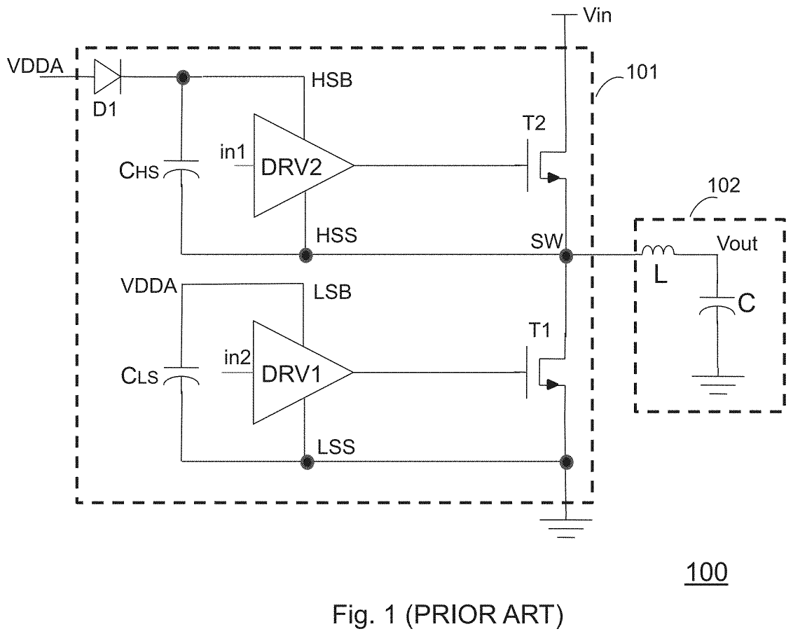

### DETAILED DESCRIPTION

### Definitions

Throughout the present disclosure, the term “node” will be used to describe any point on a circuit where connections of two or more circuit elements meet or are adapted to meet. Although nodes will be graphically represented by points in the present disclosure, the person skilled in the art will understand that a node may also present part of a line or connection between elements or circuital devices, not just a single point.

Throughout the present disclosure, the term “driver” or “driver circuit” will be used to describe an electrical circuit or other electronic component used, adapted or configured to control another circuit or component.

Throughout the present disclosure, the term “half bridge driver” will be used to describe an electronic circuit including two switches driven by their corresponding drivers. The term “high side” will be used in correspondence with a portion of such circuit including one of the switches and its corresponding driver and the term “low side” will be used in correspondence with another portion of such circuit including the other switch and its corresponding driver.

### Description

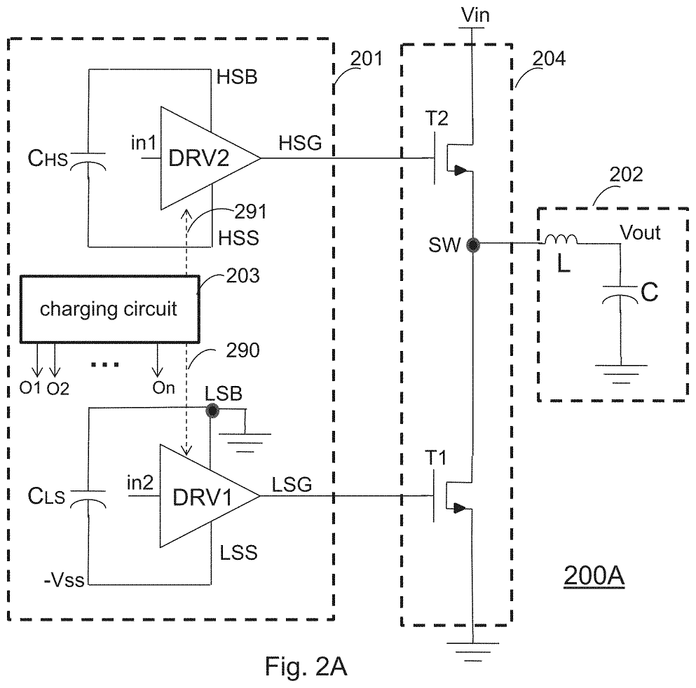

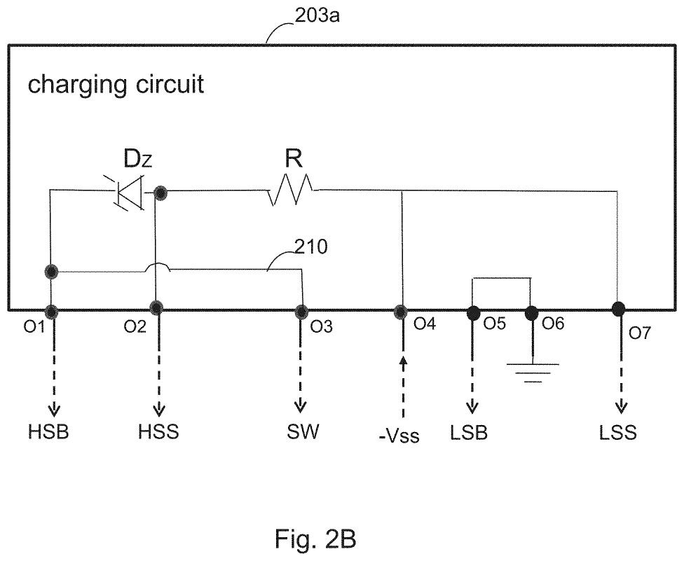

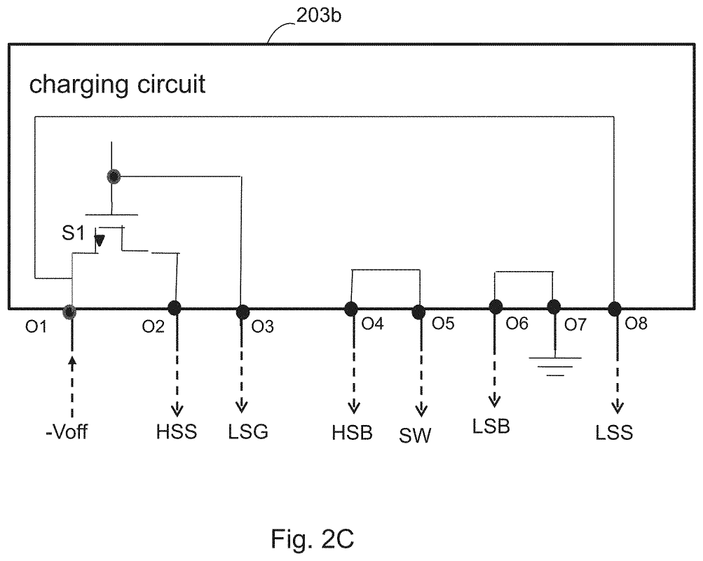

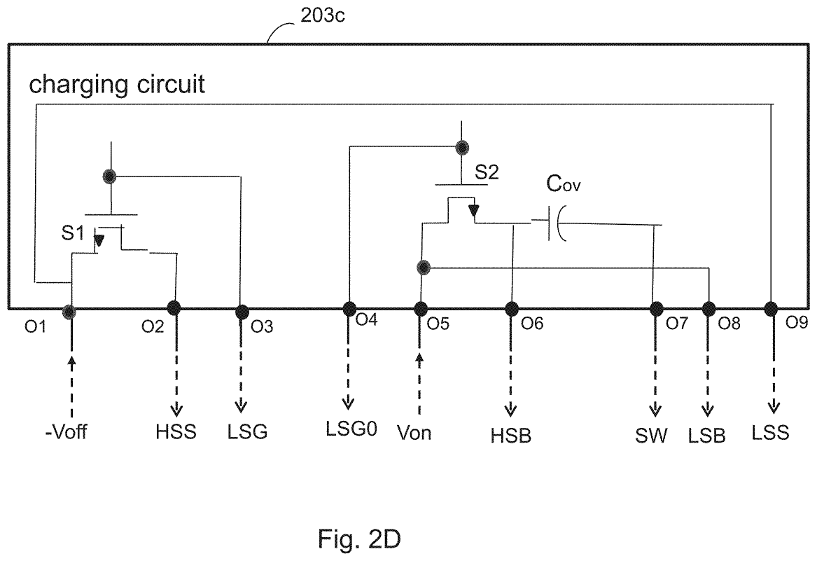

FIG. 2A shows an electronic circuit (200A) in accordance with an embodiment of the present disclosure. The electronic circuit (200A) comprises driver block (201) designed to drive mainly D-mode power FETs. Such driver can be configured to also drive E-mode FETs as will be explained later in the disclosure. The driver block (201) controls FETs T2 and T1, which are then connected to a load (202), and comprises high side and low side drivers (DRV2, DRV1), a low side capacitor (C_{LS}), and a high side capacitor (C_{HS}). According to embodiments of the present disclosure, the driver block (201) may be configured to drive a power stage (204) as shown in FIG. 2A. The power stage (204) comprises high side and low side FETs (T2, T1). An input voltage (Vin) is connected to high side FET (T2). High side and low side drivers (DRV2, DRV1) may be configured to drive high side and low side FETs (T2, Ti) through respective nodes (HSG, LSG). As described previously, a negative gate-source voltage is required to turn D-mode FETs T1 and T2 off and such FETs are normally on when zero gate-source voltage is applied.

Regarding the lower side of the driver block (201), a negative supply −V_{SS} (for example, −5 volts) is connected to node LSS and is used to supply power to low side driver (DRV1). In addition, node LSB of low side driver (DRV1) is connected to ground (THIS IS NOT SHOWN IN THE FIGURE). As such, low side capacitor (C_{LS}), connected across nodes LSB and LSS is always charged with a voltage V_{SS} served as power supplied to low side driver (DRV1). Moreover, low side driver (DRV1) is configured to provide a zero voltage at node (LSG) to turn low side FET on and a negative voltage −V_{SS} to turn low side FET (T1) off, when needed. As shown in FIG. 2A, node LSB is tied to ground, however further embodiments in accordance with the present disclosure may be envisaged wherein node LSB is connected to a positive voltage.

Further referring to FIG. 2A, the driver block (201) also comprises a charging circuit (203) which is schematically represented in the figure as including a plurality of output nodes (O₁, . . . , On). According to embodiments of the present disclosure, any output node of the plurality of output nodes (O₁, . . . , On) may be connected to one or more nodes of the electronic circuit (200A), or to a power supply or any nodes of an external electronic circuit. More in particular, as shown by arrows (290, 291), the charging circuit (203) may be connect to low side driver (DRV1) and/or high side driver (DRV2) in accordance with further embodiments of the present disclosure.

In accordance with embodiments of the present disclosure, in a first phase of operation, when low side FET (T1) is turned on, switch node (SW) is connected to ground, and charging circuit (203) is configured to a) provide a negative voltage to node (HSS) and b) a zero or positive voltage to node (HSB). As such, high capacitor (C_{HS}) is charged positively across nodes HSB-HSS and provides power supplied to high driver (DRV2) during the second phase of operation, as explained later. Continuing with the first phase of operation, high side driver (DRV2), receiving a negative voltage at node (HSS) and a zero or positive voltage at node (HSB), is configured to provide a negative voltage to node (HSG), sufficient to turn high side FET (T2) off.

In the second phase of operation, low side FET (T1) is off and the charge retained across high side capacitor (C_{HS}) is served as power supply to high side driver (DRV2). During this phase, high side driver (DRV2) is configured to provide a zero or positive voltage across the gate-source of T2 and as a result, high side FET (T2) will be on, and the voltage at switch node SW will asymptotically approach Vin, equal to or less than the voltage applied to gate of high side FET (T2). In other words, the gate-source junction of high side FET (T2) experiences either a zero or positive voltage during this phase and as a result, high side FET (T2) is turned on.

The person skilled in art will understand that high side and low side FETs (T2, T1) function like switches. Embodiments in accordance with the present disclosure may be envisaged, wherein and without departing from the spirit and scope of the invention, high side and low side FETs (T2, T1) may be replaced by switches other than FETs. The person skilled in the art will also understand that other embodiments according to the present disclosure may also be designed wherein the source of the lower side FET (T1) may be configured to receive positive or negative supply voltages instead of being tied to ground. According to embodiments of the present disclosure, the high side and low side FETs (T2, T1) may be metal-oxide FETs (MOSFETs), GaAs/GaN FETs, SiC FETs or MEMS devices.

In what follows, various implementations of the charging circuit (203) of FIG. 2A will be described in detail, in accordance with embodiments of the present disclosure.

FIG. 2B shows an exemplary charging circuit (203a) according to an embodiment of the present disclosure. The charging circuit (203a) comprises a series combination of a resistor (R) and a Zener diode (D_{Z}) and connections which can be represented as, for example, seven output nodes (O₁, . . . , O₇). As shown in FIG. 2B, the charging circuit (203a) is an implementation of the charging circuit (203) of FIG. 2A wherein the output nodes (O₁, O₂, O₃, O₇) are connected to nodes (HSB, HSS, SW, LSS) of the driver block (201) of FIG. 2A, respectively. On the other hand, node (O4) of the charging circuit (203a) is configured to receive a negative supply voltage −VSS. Node (O5) is connected to node (LSB), with nodes (O5, O6) both being tied to ground. In addition, nodes (O₁, O₃) are tied together, thus shorting node HSB and switch node SW of the driver block (201) of FIG. 2A. With continued reference to FIG. 2B, a cathode and an anode of the Zener diode (D_{Z}) are connected to nodes (O₁) and (O₂), respectively, a first end of resistor R is connected to the anode of Zener diode (D_{Z}) and a second end of resistor R is connected to node (O₄).

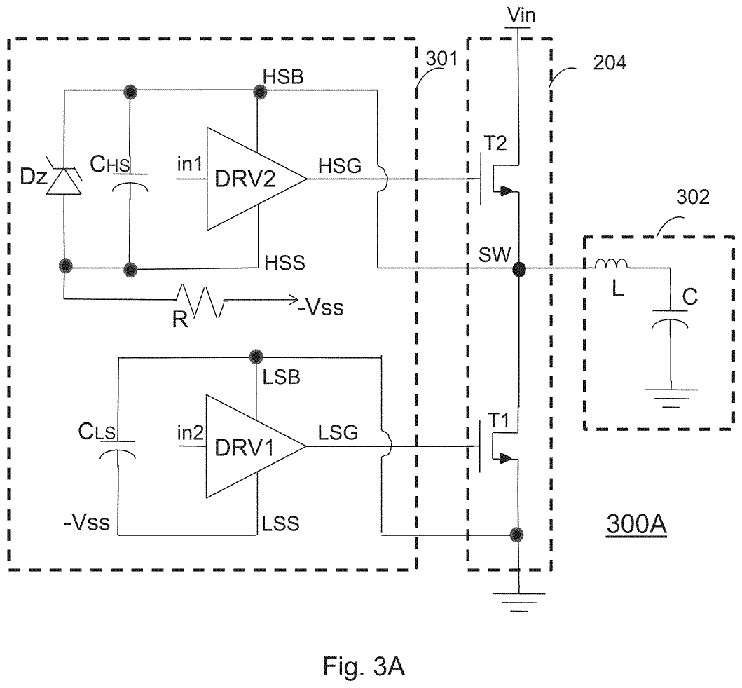

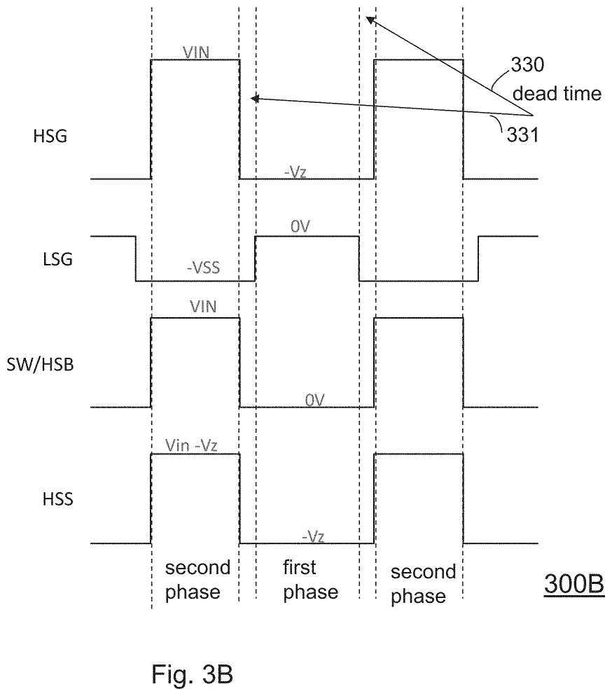

FIG. 3A shows an electric circuit (300A) comprising a driver block (301) which is equivalent to the driver block (201) of FIG. 2A wherein the charging circuit (203) is implemented as the charging circuit (203a) of FIG. 2B. The principle of operation of the electronic circuit (300) is similar to that described with regards to the electronic circuit (200) of FIG. 2A. FIG. 3B shows timing diagrams representing the steady state operation of nodes (HSG, LSG, SW, HSB, HSS) of driver block (301) of FIG. 3A. With continued reference to both FIGS. 3A-3B, and in accordance with an embodiment of the present disclosure, during the first phase of operation, low side driver (DRV1) provides zeros volts to node (LSG) to turn low side FET (T1) on. As a result, and during the same phase of operation, switch node (SW) is at ground, resistor R provides a tail current though the Zener diode (D_{Z}), and capacitor (C_{HS}) is charged to a voltage substantially equal to Zener diode (D_{Z}) breakdown voltage V_{Z} (for example 5 volts). Moreover, in the first phase, high side driver (DRV2) is configured to provide a negative voltage equal to −V_{Z} to a gate of high side FET (T2), which is the same as node (HSG), to turn this transistor off. In this configuration, it is stipulated that −V_{SS} is more negative than −V_{Z}, i.e. −V_{SS}<−V_{Z}. In the second phase, low side driver (DRV1) provides the negative voltage (−VSS) to a gate of the low side transistor (T1) to turn this transistor off. In this phase, the retained charge on high capacitor (C_{HS}) provides power supplied to driver (DRV2) which is in turn configured to provide zero volt gate-source voltage as the HSG is pulled up to HSB, to turn high side FET (T2) on and as a result, switch node (SW) is sitting at (Vin) volts during the second phase of operation. Continuing with the second phase of operation and as can be seen in FIG. 3B, node (HSS) has a voltage equal to Vin-V_{Z} and node (HSB) has a voltage equal to Vin.

The person skilled in the art will appreciate that, by virtue of connecting node (HSB) to switch node (SW), various nodes of the higher side of the driver block (301), e.g., nodes (HSB, HSS), experience voltage levels that are floating with respect to switch node (SW). According to embodiments of the present disclosure, the negative voltage (−V_{SS}) may be generated using a charge pump. In accordance with further embodiments of the present disclosure, the negative voltage (−V_{SS}) may be generated using a power supply.

As shown in FIG. 3B, the first and second phase operation will repeat in a periodic fashion and as a result, a square wave-form is generated at switch node (SW). According to embodiments of the present disclosure, high and low side FETs (T2, T1) may not turn on simultaneously to avoid possible current spike (shoot-through) that may damage the circuit. This is shown by arrows (330, 331) of FIG. 3B, which indicates the presence of a dead time provided in between consecutive first and second phases of operations. As an example, when high side FET (T2) is transitioning from on to off state (e.g., HSG transitioning from Vin to −V_{Z}), there is a delay equal to dead time before low side transistor (T1) transitions from off to on state (e.g., LSG transitioning from −V_{SS} to zero volts) ensuring that the two high and low side FETs turn on and off in complementary fashion during non-overlapping time periods. Exemplary embodiments in accordance with the present disclosure and describing how the dead time delay is generated will be given later in the disclosure.

With reference to FIG. 3A, drivers (DRV1, DRV2) may receive their respective driving input signals from driver inputs (in1, in2). According to embodiments of the present disclosure, the driver input signals may be non-overlapping square-wave signals to ultimately assure that high side and low side FETS (T2, T1) do not turn on at the same time causing current spikes (shoot-through) which may be damaging to the circuits.

With further reference to FIG. 3A, tail resistor (R) will determine the rate at which high side capacitor (C_{HS}) will get recharged. Embodiments in accordance with the present disclosure may be envisaged wherein resistor (R) is a variable resistor. According to other embodiments of the present disclosure, resistor (R) may be adjusted depending on the frequency of operation (e.g. the frequency of the square wave representing essentially the frequency at which the high and low side transistors are driven), duty cycle of the square wave and Vin voltage. In some applications, such adjustments may not be desired. In what follows, further embodiments according to the present disclosure addressing such applications are described.

FIG. 2C shows an exemplary charging circuit (203b) according to a further embodiment of the present disclosure. The charging circuit (203b) comprises a first switch (S1) and connections schematically represented as seven output nodes (O₁, . . . , O₈). As shown in FIG. 2C, the charging circuit (203b) is an implementation of the charging circuit (203) of FIG. 2A wherein the output nodes (O₂, . . . , O₆, O₈) are connected to nodes (HSS, LSG, HSB, SW, LSB, LSS) of the driver block (201) of FIG. 2A, respectively, and node (O₁) of the charging circuit (203a) receives a negative voltage −Voff. Moreover, nodes (O6, O7) are tied together and to ground. Nodes (O4, O5) are shorted together.

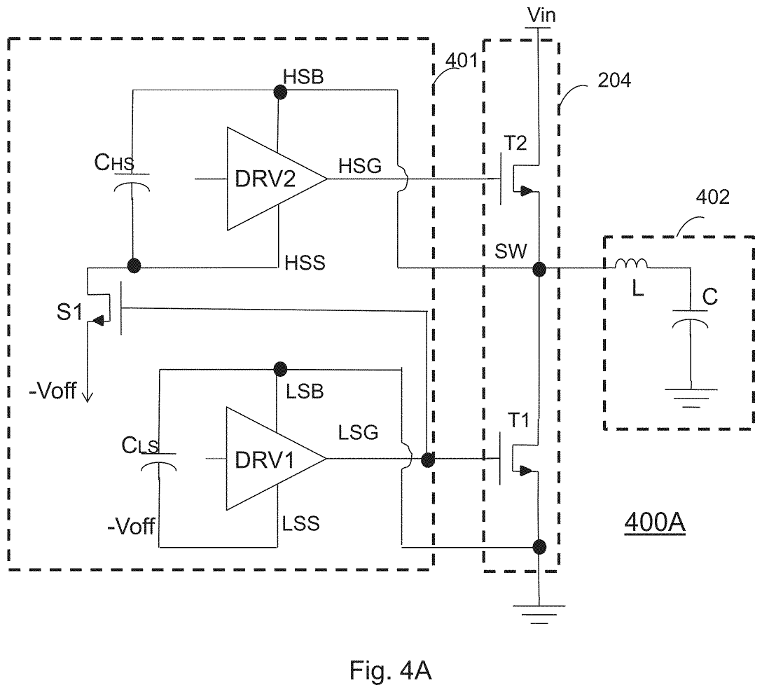

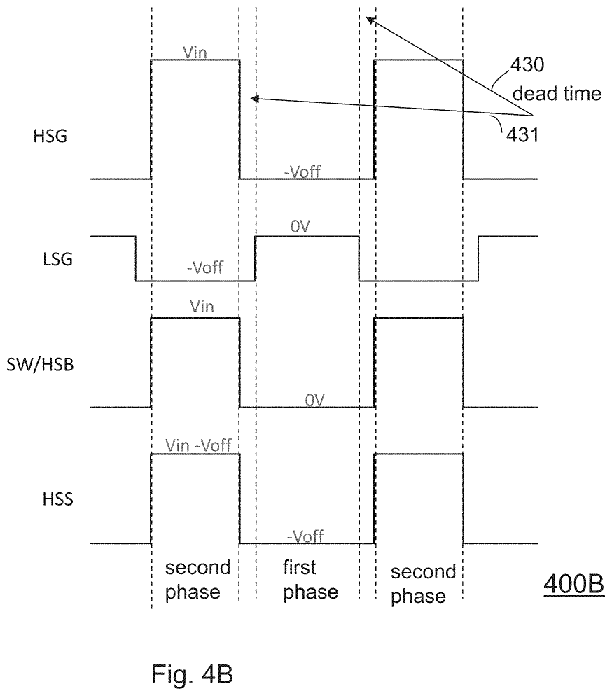

FIG. 4A shows an electric circuit (400) comprising a driver block (401) which is equivalent to the driver block (201) of FIG. 2A wherein the charging circuit (203) is implemented as the charging circuit (203b) of FIG. 2C. FIG. 4B shows timing diagrams related to steady state operation of the driver block (401) of FIG. 4A. The principle of operation and related timing diagrams of the electronic circuit (400) are similar to that described with regards to the electronic circuit (200) of FIG. 2A. In other words and referring to FIG. 4A, and regarding the lower side of the driver block (401), a negative supply −Voff (for example, −5 volts) is connected to node (LSS) and is used to supply power to low side driver (DRV1). In addition, node (LSB) of low side driver (DRV1) is connected to ground. As such, low side capacitor (C_{LS}), connected across nodes LSB-LSS is always charged with a positive voltage Voff (node LSB with respect to node LSS) served as power supplied to low side driver (DRV1). Moreover, in the first phase of operation, low side driver (DRV1) is configured to provide a zero gate-source voltage at node LSG to turn low side FET (T1) on and, a negative gate-source voltage −Voff to turn low side FET (T1) off during the second phase of operation.

As shown in FIG. 4A, first switch (S1) is essentially controlled via the voltage present at the gate of low side FET (T1), e.g. node (LSG). In the first phase, as mentioned previously, low side driver (DRV1) provides zero volts to node (LSG) to turn low side transistor (T1) on. At the same time, first switch (S1) is turned on, thus providing the negative voltage to charge the high side capacitor, and as a result, providing a positive voltage (e.g. +Voff), across nodes (HSB, HSS), which is used as a power supply to driver (DRV2) during the second phase of operation. As also shown in FIG. 4B, voltage levels at nodes (HSB) and (HSS) are Vin/0V and Vin−Voff/−Voff respectively, meaning and effective voltage of +Voff is present across high capacitor (C_{HS}) during the second phase of operation.

With continued reference to FIGS. 4A-4B, and during the first phase of operation, high side driver (DRV2) is configured to supply a negative voltage −Voff to node (HSG) to turn high side FET (T2) off. In the second phase, low side driver (DRV1) will provide a negative voltage (−Voff) to node LSG to turn low side FET (T1) off. In this phase, and as mentioned previously, high side driver (DRV2) is powered through the charge retained in high side capacitor (C_{HS}) and high side FET (T2) is turned on by receiving zero volts at its gate-source and as a result, switch node (SW) will go high (e.g. Vin). In this phase HSG is pulled up to the HSB voltage, therefore, as SW node rises to Vin, HSG node rises to Vin as well, to maintain a zero volt gate-source voltage on T2. As mentioned previously, and as a result of driving low side and high side drivers to complementary high and low states using non-overlapping control signals, a square wave signal is generated at switch node (SW). Such square wave signal will be filtered and thus shaped, depending how a load (402) is designed. By way of example, and not of limitation, the load (402) may be designed such that the output voltage Vout will be a DC voltage with a voltage level which will depend on Vin and the duty cycle of the square wave generated at switch node (SW). With reference to FIG. 4A, and according to embodiments of the present disclosure, the negative voltage (−Voff) may be generated using a charge pump. In accordance with further embodiments of the present disclosure, the negative voltage (−Voff) may be generated using a power supply.

In general, D-mode FETs show a better (lower) on resistance (Ron) than an equivalent E-mode FET when driven to a slightly positive voltage across their gate-source instead of 0V. In what follows, embodiments in accordance with the present disclosure and providing such benefit are described.

FIG. 2D shows a charging circuit (203c) according to other embodiments of the present disclosure. The charging circuit (203c) comprises a first switch (S1), a second switch (S2) and eight output nodes (O₁, . . . , O₉). As shown in FIG. 2D, the charging circuit (203c) is an implementation of the charging circuit (203) of FIG. 2A wherein the output nodes (O₂, O₃) are connected to nodes (HSS, LSG) of the driver block (201) of FIG. 2A, respectively, node (O4) is connected to LSG0 which is level shifted version of node (LSG) of the driver block (201) of FIG. 2A, nodes (O₆, O₇, O₈, O₉) are connected to nodes (HSB, SW, LSB, LSS) of the driver block (201) of FIG. 2A, respectively, and nodes (O₁, O₅) are configured to receive a negative supply voltage −Voff and a positive supply voltage Von, respectively. Moreover, nodes (O5, O8) are tied together.

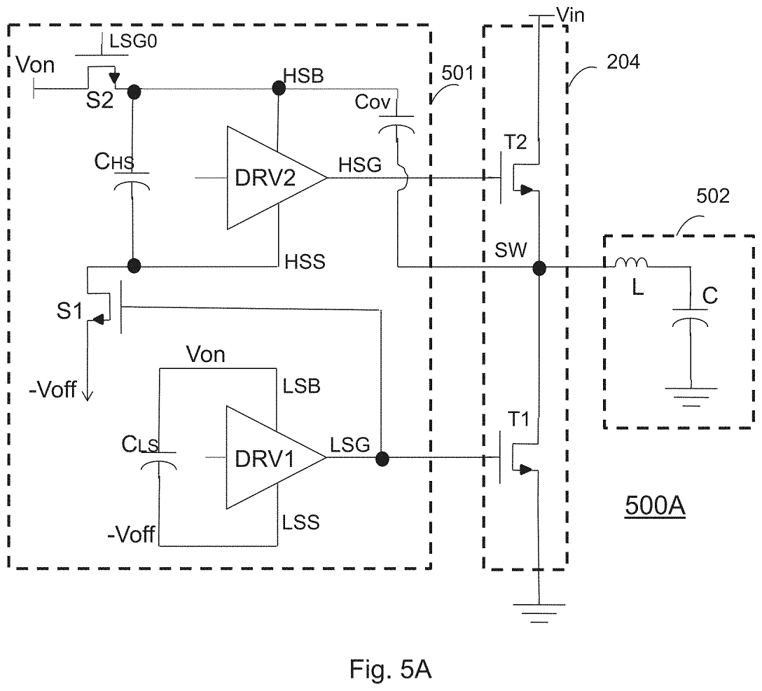

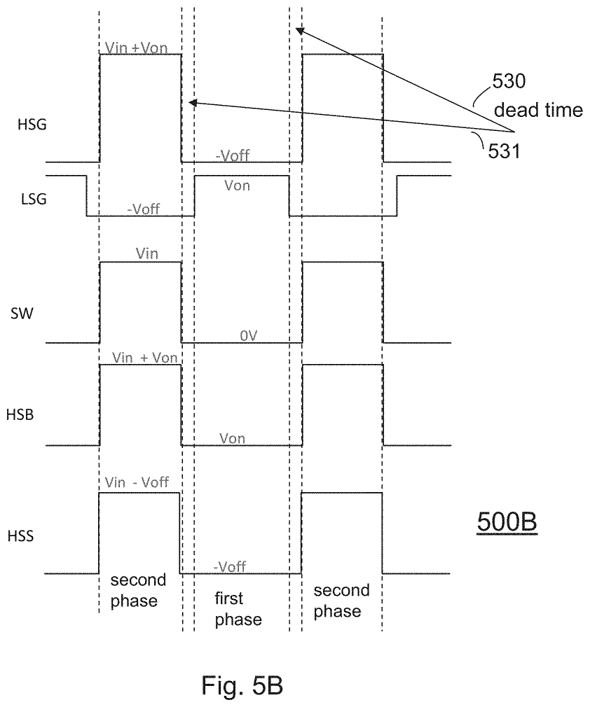

FIG. 5A shows an electric circuit (500A) comprising a driver block (501) which is equivalent to the driver block (201) of FIG. 2A wherein the charging circuit (203) is implemented as the charging circuit (203c) of FIG. 2D. For the most part, the driver block (501) has a similar architecture as the driver block (401) of FIG. 4A, except for some differences. In other words, the principle of operation of the electronic circuit (500A) is similar to that described with regards to the electronic circuit (400A) of FIG. 4A, except that, in order to exhibit even lower on resistances Ron, low and high side transistors (T1, T2) are driven with positive gate-source voltages when turned on, instead of zero volts. With reference to FIG. 5A, and in addition to first switch (S1), the driver block (501) further comprises a second switch (S2) connected in series with capacitor (C_{OV}). The series combination of second switch (S2) and capacitor (C_{OV}) is configured to receive a positive supply voltage Von at one end, and is connected to switch node (SW) at another end. Such series combination of second switch (S2) and capacitor (C_{OV}) is used to provide positive over-drive voltage to node (HSG) with respect to SW node when high side FET (T2) is turned on. Moreover, low side driver (DRV2) is powered with the positive voltage Von (as opposed to zero volts) and a negative voltage −Voff. As such, in the first phase, low side transistor (T1) is turned on by low side driver (DRV1) providing the positive voltage Von to node LSG. As a result, and during the first phase, first switch (S1) is on, thereby providing a negative voltage to node (HSS).

With further reference to FIG. 5A, the person skilled in the art will appreciate that, similarly as to that described with regards to embodiments shown in FIGS. 3A and 4A, the high side circuitry of the driver block (501) has its effective ground connected to switch node (SW) and HSB and HSS supply nodes are floating with respect to SW node, thus exhibiting floating voltage values at (HSG) with respect to switch node (SW) and during the second phase of operation. As such, a gate of second switch (S2) receives a level-shifted version of voltage levels at node LSG (LSG0) to turn on as required during the second phase of operation. By virtue of first and second switches (S1, S2) being turned on during the first phase as described, high side capacitor (C_{HS}) and capacitor (C_{OV}) get charged to Von+Voff and Von volts, respectively. The retained charge across high side capacitor (C_{HS}) will be served as power supply to high side driver (DRV2) during the subsequent (second) phase of operation. During the first phase of operation, high side driver (DRV2) is configured to provide the negative voltage −Voff to node HSG to turn high side FET (T2) off.

With further reference to FIG. 5A, and similarly to that described with regards to FIG. 4A, in the second phase of operation, low side driver (DRV1) provides the negative voltage −Voff to turn low side FET (T1) off and high side FET (T2) is over-driven to a positive voltage Von provided by high side driver (DRV2). As a result, the voltage level at switch node (SW) will go high and the mechanism of producing the output voltage Vout is similar to that described with regards to embodiments shown in FIGS. 3A and 4A. FIG. 5B, shows timing diagrams (500B) associated with the steady-state operation of the driver block (501). The timing diagrams (500B) are similar to the timing diagrams (400B) of FIG. 4B, except that during the second phase of operation, nodes HSB and HSG will experience a voltage level of Vin+Von, instead of Vin as described previously with regards to the driver block (401) of FIG. 4A. In other words, and by virtue of having an additional capacitor (C_{OV}), high side FET (T2) receives a positive voltage, Von, across its gate-source when turned on, thus providing the benefit of having a smaller on resistance Ron for applications desiring such lower resistance. It is pointed out that both low side and high side FETs (T1, T2) receive an overdrive of approximately Von, allowing smaller on resistance for both FETs.

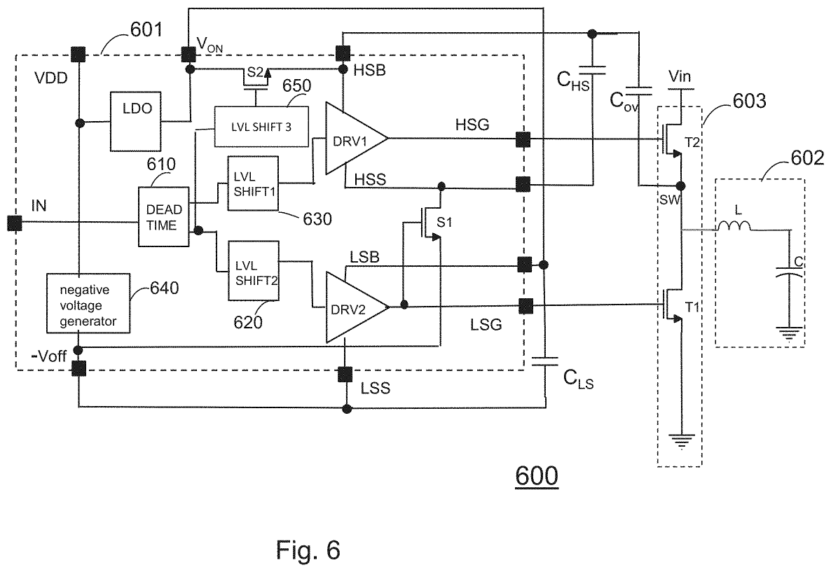

FIG. 6 shows an electronic circuit (600) comprising a driver block (601) driving a power stage (603) which is connected to a load (602). The power stage (603) comprises a high side FET (T2) and a low side FET (T1). According to an embodiment of the present disclosure high side and low side FETs (T2, T1) are D-mode FETs. The driver block (601) comprises nodes (VDD, Von, HSB, HSG, HSS, LSB, LSG, LSS, −Voff, IN, SW), high side and low side drivers (DRV2, DRV1), switches (S1, S2), a timing block (610), a high side, a low side level shifter and a S2 level shifter (630, 620, 650). Functionalities and interactions of switches (S2, S1), high side and low side drivers (DRV2, DRV1), high side and low side FETs (T2, T1) and the load (602) are similar to that described with regards to the electronic circuit (500A) of FIG. 5A. The same applies to high side capacitor (C_{HS}), low side capacitor (C_{LS}) and capacitor (C_{OV}) with connection points and functionalities similar to their respective counterparts as shown in FIG. 5A. According to embodiments of the present disclosure, the driver block (601) may have one or more nodes.

With further reference to FIG. 6, a control signal, used to ultimately provide driving signals to drive high and low side drivers (DRV2, DRV1), may be received through input node (IN). The timing block (610) will then use the control signal to provide two separate, non-overlapping square wave control signals with proper in-between dead times, similar to that described with regards to timing diagrams (300B, 400B, 500B) of FIGS. 3B, 4B and 5B. The square wave control signals are then fed to their respective S2, high and low side level shifters (650, 630, 620) to provide properly level shifted driving signals to drive both high side and low side driver and switch S2 (DRV2, DRV1, S2). Moreover, the driving signal input to the low side level shifter (620) may also be used to level shifter for gate control of switch (S2). Depending on the voltage level of V_{ON}, this gate control can be level shifted by level shifter circuit (650 to provide a gate signal sufficiently above V_{ON} to turn S2 device robustly on.

By way of example, referring to timing diagrams (500B) of FIG. 5B, low driver (DRV1) may be configured to provide voltage levels −Voff and Von to node LSG to turn low side FET (T1) off and on respectively; high side driver (DRV2) may be configured to provide voltage levels −Voff and Vin+Von to node HSG to turn high side FET (T2) off and on respectively; and gate control voltage levels Vhsb and Von+5V could turn switch (S2) off and on respectively. As such, proper level shifting may be applied by high and low side level shifters (630, 620) to assure such configurations of high and low side drivers (DRV2, DRV1). The driving block (601) further comprises a negative voltage generator (640) receiving positive voltage from node (VDD) to generate negative voltage −Voff. The negative voltage generator (640) may comprise a charge pump in accordance with an embodiment of the present disclosure. A voltage regulator (LDO) also shown in FIG. 6, is used to generate a regulated positive voltage (Von) fed to a drain of switch (S2).

With regards to capacitances (C_{HS}, C_{LS}, C_{OV}), their functionality and interaction with the rest of the electronic circuit (600) of FIG. 6 are similar to that described with regards to their counterparts shown in FIG. 5A. In other words, by virtue of charging capacitor (C_{OV}) during the first phase of operation when lower side FET (T1) is in the ON state, higher side FET (T2) is overdriven when being turned on during the second phase of operation, thus providing the benefit of having an improved on resistance Ron during operation. It is pointed out that both low side and high side FETs (T1, T2) receive on overdrive of approximately Von, allowing smaller on resistance for both FETs.

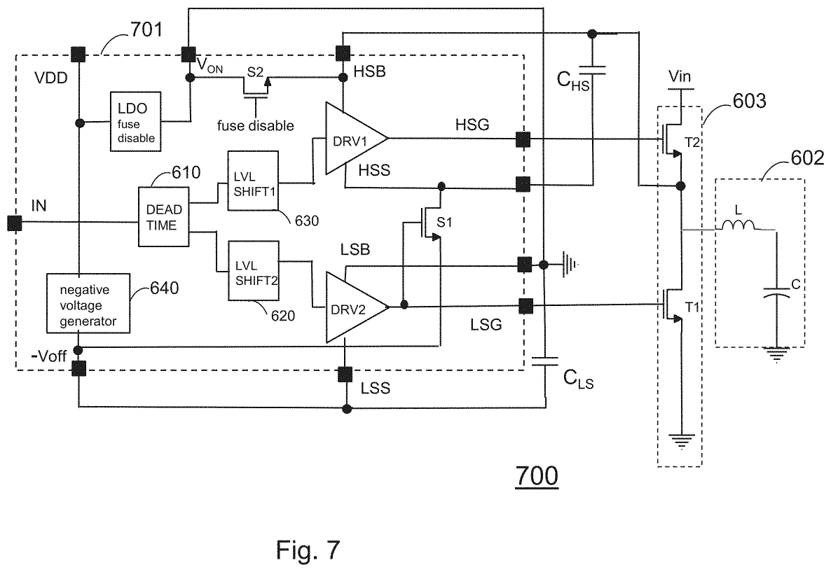

FIG. 7 shows an electronic circuit (700) in accordance with further embodiments of the present disclosure, comprising a driver block (701) driving a power stage (603) which is connected to a load (602). The principle of operation of the driver block (701) is similar to that described with regards to the driver block (601), except that driver block (701) of FIG. 7, has the flexibility of being used in two different applications, with or without gate overdrive. As can be seen in FIG. 7, voltage regulator (LDO) and switch (S2) may be fuse disabled according to an embodiment of the present disclosure. In this scenario, the driver block (701) has similar functionality as to that described with regards to the half-bridge driver (401) of FIG. 4A wherein the gate of high side FET (T2) is not overdriven. In a scenario when voltage regulator (LDO) and switch (S2) are not disabled, the driver block (701) will provide similar functionality as that described with regards to the driver block (601) of FIG. 6. (A third figure may be added to show that the same architecture can be used to drive e-mode FETs as well with no modification required to the internal circuitry shown in FIGS. 6 and 7 i. e 601 and 701)

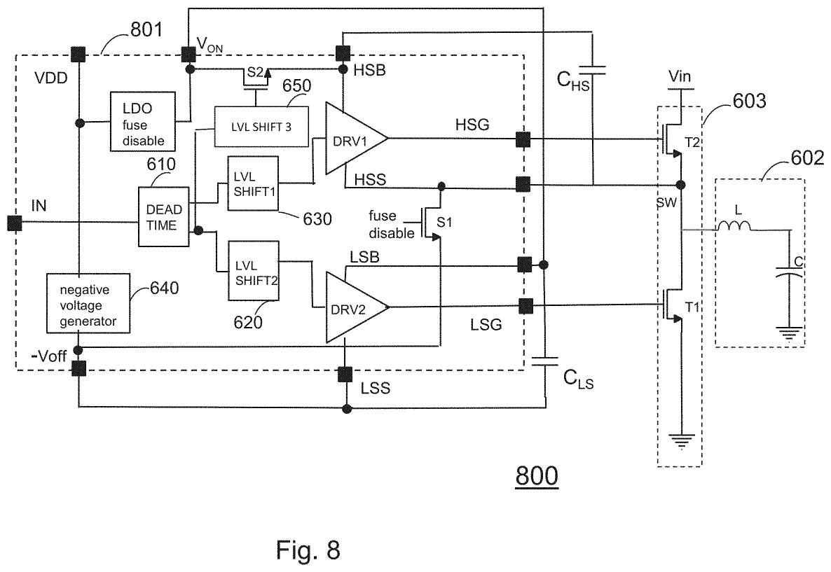

FIG. 8 shows an electronic circuit (800) in accordance with further embodiments of the present disclosure, comprising a driver block (801) driving a power stage (603) which is connected to a load (602). The principle of operation of the driver block (801) is similar to that described with regards to the driver block (701) of FIG. 7, except that switch (S1) of the electronic circuit (800) may be fuse disabled. The person skilled in the art will appreciate that in the scenario where the switch (S1) of FIG. 8 is fuse disabled, the driver block (801) may be used to drive E-mode (FETs) and using practically the same structure.

With reference to FIGS. 2A, 3A, 4A and 5A, according to embodiments of the present disclosure, constituents of each of the driver blocks (201, 301, 401, 501) may be implemented on the same chip or on separate chips. With reference to FIG. 6, a combination of constituents of the driving block (601), capacitors (C_{HS}, C_{LS}, C_{OV}) and the FET block (603) may be implemented on the same or separate chips. Similarly, and with reference to FIG. 7, a combination of constituents of the driving block (701), capacitors (C_{HS}, C_{LS}, C_{OV}) and the FET block (603) may be implemented on separate chips.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, or parallel fashion.

It is to be understood that the foregoing description is intended to illustrate and not to limit the scope of the invention, which is defined by the scope of the following claims, and that other embodiments are within the scope of the claims. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

The term “MOSFET”, as used in this disclosure, means any field effect transistor (FET) with an insulated gate and comprising a metal or metal-like gate electrode, insulator, and semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As should be readily apparent to one of ordinary skill in the art, various embodiments of the invention can be implemented to meet a wide variety of specifications. Unless otherwise noted above, selection of suitable component values is a matter of design choice and various embodiments of the invention may be implemented in any suitable IC technology (including but not limited to MOSFET structures), or in hybrid or discrete circuit forms. Integrated circuit embodiments may be fabricated using any suitable substrates and processes, including but not limited to standard bulk silicon, silicon-on-insulator (SOI), and silicon-on-sapphire (SOS). Unless otherwise noted above, the invention may be implemented in other transistor technologies such as Bulk CMOS, BCD, BiCMOS, bipolar, GaAs HBT, GaN HEMT, GaAs pHEMT, and MESFET technologies. However, the inventive concepts described above are particularly useful with an SOI-based fabrication process (including SOS), and with fabrication processes having similar characteristics. Fabrication in CMOS on SOI or SOS processes enables circuits with low power consumption, the ability to withstand high power signals during operation due to FET stacking, good linearity, and high frequency operation (i.e., radio frequencies up to and exceeding 50 GHz). Monolithic IC implementation is particularly useful since parasitic capacitances generally can be kept low (or at a minimum, kept uniform across all units, permitting them to be compensated) by careful design.

Voltage levels may be adjusted or voltage and/or logic signal polarities reversed depending on a particular specification and/or implementing technology (e.g., NMOS, PMOS, or CMOS, and enhancement mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functional without significantly altering the functionality of the disclosed circuits.

1.-30. (canceled)

31. An electronic circuit comprising:
a high side driver;
a high side capacitor connected across the high side driver;
a low side driver;
a low side capacitor connected across the low side driver;
and
a charging circuit;
wherein:
the electronic circuit is connectable to an output load at an electronic circuit output;
the low side driver is configured to selectively provide a first driving voltage and a third driving voltage to drive a power stage;
the high side driver is configured to selectively provide a second driving voltage and a fourth driving voltage to drive the power stage; and
the charging circuit is connected to the high side capacitor and configured to provide power to the high side driver when the high side driver is in off state.

32. The electronic circuit of claim 31, wherein the high side driver and the low side driver are configured to control a series arrangement of a high side switch and a low side switch, a combination of the high side switch and the low side switch being configured to receive a first supply voltage.

33. The electronic circuit of claim 32, wherein the charging circuit comprises a second supply voltage, wherein a portion of the second supply voltage is coupled across the high side capacitor.

34. The electronic circuit of claim 33, wherein the charging circuit comprises a Zener diode.

35. The electronic circuit of claim 33, wherein the series arrangement of a high side switch and a low side switch comprises a depletion mode FET switch.

36. The electronic circuit of claim 35, wherein the low side driver is configured to receive the second supply voltage and a third supply voltage.

37. The electronic circuit of claim 36, wherein the third supply voltage is at ground, the second supply voltage is a negative voltage and the first supply voltage is a positive voltage.

38. The electronic circuit of claim 37, wherein:
in a first state:
the first driving voltage is equal to or positive with respect to ground;
the charging circuit provides current to charge the high side capacitor, thereby providing power supplied to the high side driver during a second state; and
the second driving voltage is negative with respect to ground;
in the second state:
the third driving voltage is negative with respect to ground; and
the fourth driving voltage is equal to or positive with respect to ground.

39. The electronic circuit of claim 38, wherein:
the first and the fourth driving voltages are substantially equal to the third supply voltage; and
the second and the third driving voltages are substantially equal to the second supply voltage.

40. The electronic circuit of claim 37, wherein the second supply voltage is provided by a charge pump.

41. The electronic circuit of claim 40, integrated in one die or chip.

42. The electronic circuit of claim 36, wherein:
the charging circuit comprises a switch FET having a gate connected at an output of the low side driver; a drain connected to a first end of the high side capacitor and a source connected to the third supply voltage; and
a second end of the high side capacitor is connected to the electronic circuit output.

43. The electronic circuit of claim 42, wherein the low side driver is configured to receive a second supply voltage and a third supply voltage.

44. The electronic circuit of claim 43, wherein the third supply voltage is at ground, the first supply voltage is a positive voltage and the second supply voltage is a negative voltage.

45. The electronic circuit of claim 44, wherein:
in a first state:
the first driving voltage is positive with respect to ground, thereby charging the high side capacitor through the second supply voltage, thus providing power supplied to the high side driver during in a second state; and
the second driving voltage is negative with respect to ground;
in the second state:
the third driving voltage is negative with respect to ground; and
the fourth driving voltage is positive with respect to ground.

46. The electronic circuit of claim 45, wherein:
the first and the fourth driving voltages are substantially equal to the third supply voltage; and
the second and the third driving voltages are substantially equal to the second supply voltage.

47. The electronic circuit of claim 44, wherein the second supply voltage is provided by a charge pump.

48. The electronic circuit of claim 44, integrated in one die or chip.

49. The electronic circuit of claim 36, wherein the charging circuit comprises:
a capacitor;
a first switch FET having:
(i) a gate connected at an output of the low side driver;
(ii) a drain connected to a first end of the high side capacitor; and
(iii) a source connected to the second supply voltage; and
a second switch FET having:
(i′) a gate configured to receive a fourth supply voltage;
(ii′) a drain configured to receive a fifth supply voltage; and
(iii′) a source connected to a second end of the high side capacitor and to a first end of the capacitor;
wherein:
the second end of the capacitor is connected to the electronic circuit output; and
the low side driver is configured to receive the second supply voltage and the fifth supply voltage.

50. The electronic circuit of claim 49, wherein the third supply voltage is ground, the first, the fourth and the fifth supply voltages are positive voltages and the second supply voltage is a negative voltage.

51. The electronic circuit of claim 50, wherein the second supply voltage is provided by a charge pump.

52. The electronic circuit of claim 51, integrated in one die or chip.

53. The electronic circuit of claim 50, wherein:
in a first state:
i) the first driving voltage is positive with respect to ground;
ii) the second switch FET is configured to turn on receiving the fourth supply voltage;
thereby:
charging the high side capacitor to provide power supplied to the high side driver during in a second state; and
iii) the second driving voltage is negative with respect to ground;
in the second state:
i′) the third driving voltage is negative with respect to ground and
ii′) the fourth driving voltage is equal to or positive with respect to ground.

54. The electronic circuit of claim 53, wherein:
the first driving voltage is substantially equal to the fifth supply voltage and the fourth driving voltage is substantially equal to a sum of the first and the fifth supply voltages; and
the second and the third driving voltages are substantially equal to the third supply voltage.

55. The electronic circuit of claim 49, further comprising:
a first level shifter driving the low side driver;
a second level shifter driving the high side driver;
a third level shifter driving the second switch FET;
a timing block configured to receive input from an electronic circuit input and to generate a first control signal and a second control signal;
a negative supply voltage generator configured to receive a positive input supply voltage to generate the second supply voltage; and
a voltage regulator configured to receive the positive input supply voltage to generate the fifth supply voltage;
wherein:
the first control signal is used to drive the first level shifter and to gate control the second switch FET; and
the second control signal is used to drive the second level shifter.

56. The electronic circuit of claim 55, wherein the voltage regulator and the second switch FET are fuse disabled.

57. The electronic circuit of claim 31 configured to receive:
a first control signal to drive the low side driver; and
and a second control signal to drive the high side driver.

58. The electronic circuit of claim 57, wherein there is a set dead time in-between the first control signal and the second control signal.

59. An electronic circuit comprising:
a high side driver;
a high side capacitor connected across the high side driver;
a low side driver;
a low side capacitor connected across the low side driver;
a high side switch serially connected to a low side switch at an electronic circuit output, and
a charging circuit;
wherein:
the electronic circuit is connectable to an output load at the electronic circuit output;
the high side driver is connected to the high side switch;
the low side driver is connected to the low side switch;
the low side driver is configured to selectively turn the high side switch on or off;
the high side driver is configured to selectively turn the low side switch on or off; and
the charging circuit is connected to the high side capacitor and configured to provide power to the high side driver when the high side driver is in off state.

60. The electronic circuit of claim 59, wherein:
the high side switch and the low side switch comprise depletion mode FETs; and
the output load comprises a low pass filter.

61. A method of generating first, second, third and fourth driving voltages comprising:
providing a high side driver;
connecting a high side capacitor across the high side driver;
providing a low side driver;
connecting a low side capacitor across the low side driver;
applying a negative supply voltage to the low side driver;
in a first state:
configuring the low side driver to provide the first driving voltage being equal to or positive with respect to ground;
charging the high side capacitor to generate a charged high side capacitor;
configuring the high side driver to provide the second driving voltage being negative with respect to ground;
in a second state:
supplying power to the high side driver using the charged high side capacitor;
configuring the low side driver to generate the third driving voltage being negative with respect to ground;
